(19) United States
(12) Patent Application Publication
(10) Pub. No.: US 2026/0220764 A1
(43) Pub. Date: Jul. 30, 2026

(54) Learning Model Matching Region Detection Device, Learning Model Matching Region Detection Method, and Learning Model Operation Method

(71) Applicant: Hitachi High-Tech Corporation, Minato-ku, Tokyo (JP)

(72) Inventors: Munetoshi UNUMA, Tokyo (JP); Sota KOMATSU, Tokyo (JP); Masayoshi ISHIKAWA, Tokyo (JP); Yasutaka TOYODA, Tokyo (JP); Tomoyuki OKUDA, Tokyo (JP); Takahiro MOTOYOSHI, Tokyo (JP)

(21) Appl. No.: 19/159,119

(22) PCT Filed: Apr. 25, 2023
(86) PCT No.: PCT/JP2023/016216

§ 371 Date: Aug. 22, 2025

(51) Int. Cl. G06T 7/00; G06T 5/60

(52) U.S. Cl. CPC G06T 7/001; G06T 5/60; G06T 2207/30148

(57) ABSTRACT

To provide a learning model matching region detection device, a learning model matching region detection method, and a learning model operation method that are suitable for verification and correction of a matching region of a learning model in machine learning. A learning model matching region detection device includes: an image quality improvement processing unit that converts a low-quality image into a quality-improved image as a high-quality image by using a learning model; a model matching region storage unit that stores a region of learned information as a model matching region in a learning step of the learning model; a model matching region accuracy verification unit that verifies accuracy of a measured value determined from the quality-improved image with reference to a measured value of the high-quality image; and a model matching region correction processing unit that corrects the model matching region in the model matching region storage unit by using the accuracy of accuracy improvement information detected by the model matching region accuracy verification unit.

### TECHNICAL FIELD

The present invention relates to a learning model matching region detection device, a learning model matching region detection method, and a learning model operation method that detect a matching region of a learning model and is suitable for verification and correction.

### BACKGROUND ART

When various systems or processes are configured using a learning model in machine learning, it is necessary to properly determine the matching region of the learning model. In order to obtain a proper matching region, it is necessary to verify the validity of the matching region and correct an improper region to a proper region.

As a specific example of such a request, for example, a device is used with an electron microscope to measure the shape of a circuit pattern formed on a wafer. In this case, for example, it is assumed that an image quality improvement system converts a low-quality image into a high-quality image and a length measuring system is used with a quality-improved image.

When a circuit pattern formed on a wafer is imaged using an electron microscope, an electron beam is emitted to the wafer and electrons having bounced back are detected by a detector to obtain a captured image. When the wafer is irradiated with an electron beam, the electron beam may erode the circuit pattern, resulting in damage to the circuit pattern formed on the wafer. Thus, it is desired to obtain a captured image with a small amount of electron beam irradiation.

However, an image obtained by a small amount of electron beam irradiation may contain a large amount of particulate noise and thus is not suitable for shape measurement (hereinafter will be referred to as a low-quality image). In shape measurement using an image, the edge portion of a circuit pattern is detected by image processing, and a distance from a target measurement location is measured by the number of pixels of the image. In the presence of particulate noise, the edge portion may become unclear and the particulate noise may be misidentified as the edge portion of the circuit pattern.

Thus, in order to reduce such particulate noise, the same shooting location is photographed multiple times, and the integration average of the image is obtained to reduce noise (hereinafter this image will be referred to as a high-quality image).

The high-quality image is identical to an image of a true circuit pattern (a high-quality image without noise). Accurate image measurement can be conducted by using this image. Hereinafter, a measured value in this image is assumed to be a true value.

However, in order to obtain a high-quality image, it is necessary to collect multiple low-quality images. This means that the wafer is irradiated with a large amount of electron beams and thus is seriously damaged. Therefore, it is necessary to obtain a high-quality image and perform accurate image measurement by using a method different from the method for capturing multiple low-quality images and obtaining a high-quality image.

In contrast, as an example of a method for obtaining (predicting) a high-quality image from a low-quality image, a method for improving image quality using AI (machine learning) is available. In the method for improving image quality using AI, image quality is properly improved but a side effect may occur and adversely affect image measurement. Therefore, the side effect needs to be alleviated.

As an example of a system that converts a low-quality image to a high-quality image by using machine learning, a system described in PTL 1 generates the learning model of machine learning by using a low-quality image and a high-quality image and converts an input image of low quality to a high-quality image by using the learning model through machine learning.

### CITATION LIST

### Patent Literature

PTL 1: WJ21/095256

### SUMMARY OF INVENTION

### Technical Problem

The system described in PTL 1 is a system that improves image quality using AI, and a learning model is prepared in advance for each purpose of improvement in image quality. For example, in order to remove noise, a learning model for removing noise is prepared according to the level of noise. To improve an aberration, a learning model is prepared according to the aberration size. In this state, a user selects a learning model according to the purpose of improving image quality or the state of image quality (the state of noise or aberration) of a low-quality image, and performs an image improvement process.

However, in the method of PTL 1, a user visually determines and selects a learning model. Thus, the selected learning model may not be effective for improving the quality of an image to be processed (hereinafter this state is assumed to be a learning model mismatch). Furthermore, the learning model is designed for each purpose, that is, noise removal or improvement in aberration. For a combination of the purposes (for example, improvement in both noise removal and aberration), any measures are not described in PTL 1.

In addition, since the system described in PTL 1 is a system for improving image quality, when image quality is improved using AI, even visually preferable noise removal from an image may cause a side effect, for example, such as a shape pattern moving in the image depending on the learning model after learning. In this case, when an image with improved image quality is used for image measurement, such an improper movement of a shape pattern may reduce the accuracy of measurement, which is a process to be avoided. PTL 1 does not describe any side effects that may occur in such a process of improving image quality with AI, or measures against such side effects.

Under these circumstances, an object of the present invention is to provide a learning model matching region detection device, a learning model matching region detection method, and a learning model operation method that are suitable for verification and correction of a matching region of a learning model in machine learning.

### Solution to Problem

According to the above, this invention provide “a learning model matching region detection device which includes: an image quality improvement processing unit that converts a low-quality image into a quality-improved image as a high-quality image by using a learning model; a model matching region storage unit that stores a region of learned information as a model matching region in a learning step of the learning model; a model matching region accuracy verification unit that verifies accuracy of a measured value determined from the quality-improved image with reference to a measured value of the high-quality image; and a model matching region correction processing unit that corrects the model matching region in the model matching region storage unit by using the accuracy of accuracy improvement information detected by the model matching region accuracy verification unit.”

According to the present invention, there is provided “a method for detecting a learning model matching region which includes: converting a low-quality image into a quality-improved image as a high-quality image by using a learning model; storing a region of learned information as a model matching region in a learning step of the learning model; verifying accuracy of a measured value determined from the quality-improved image with reference to a true measured value; and correcting the model matching region by using the accuracy of accuracy improvement information.”

According to the present invention, there is provided “a learning model operation method which includes: a learning step of obtaining a learning model for estimating a quality-improved image from a low-quality image using AI and storing a region of learned information as a model matching region; and an operation step of determining whether an accuracy improving state when, by using the learning model, the quality-improved image is estimated from the low-quality image and an image is measured using the quality-improved image is information about the model matching region of the learning model on the basis of the information about the model matching region, verifying the accuracy improving state with reference to the high-accuracy information, and correcting the model matching region by using accuracy of the accuracy improving state.”

According to the present invention, there is provided “a learning model matching region detection device which includes: an improvement processing unit that converts low-accuracy information into improvement information with high accuracy by using a learning model; a model matching region storage unit that stores a region of learned information as a model matching region in a learning step of the learning model; a model matching region accuracy verification unit that verifies accuracy of a measured value determined from the improvement information, with reference to a measured value of high-accuracy information; and a model matching region correction processing unit that corrects the model matching region in the model matching region storage unit by using the accuracy of accuracy improvement information detected by the model matching region accuracy verification unit.”

### Advantageous Effects of Invention

The present invention can provide a matching region detection device for a machine learning model and a method thereof that are suitable for verification and correction of a matching region of a learning model in machine learning.

Specifically, according to embodiments of the present invention, a reduction in accuracy of measurement in image measurement can be recognized by a notification about a mismatched learning model. This can prevent a reduction in the accuracy of measurement when using an improperly converted image.

Furthermore, according to the embodiments of the present invention, even in a measurement region where a learning model to be used is not preregistered with a model matching region, the model matching region of the learning model can be added or deleted by verifying the accuracy of measurement during an operation.

### BRIEF DESCRIPTION OF DRAWINGS

FIG. 1 shows a configuration example for particularly determining a model matching region in a matching region detection device for a learning model and a method thereof according to a first embodiment of the present invention.

FIG. 2 shows an example of the upper and lower layers of a multilayer structure semiconductor pattern.

FIG. 3 shows a relationship between a low-quality image and a quality-improved image and a high-quality image.

FIG. 4 shows a configuration example of a processing block of OVL measurement.

FIG. 5 shows a state of occurrence of a measurement error inside and outside a learning region.

FIG. 6 shows a state of occurrence of an error inside the learning region.

FIG. 7 shows a state of transition of a model matching region inside the learning region.

FIG. 8 shows a processing block during an actual operation.

FIG. 9 shows an example in which the accuracy of measurement increases outside the learning region.

FIG. 10 shows a state of transition of a model matching region outside the learning region.

FIG. 11 shows an example of measurement of a point shape.

### DESCRIPTION OF EMBODIMENTS

Hereinafter, embodiments of the present invention will be described with reference to the drawings.

### First Embodiment

In a learning model matching region detection device and a method thereof according to a first embodiment of the present invention, an application to an example of an image quality improvement system and a length measuring system using a quality-improved image will be described.

Particularly in the first embodiment, the accuracy of a model matching region will be verified and a reduction of a region will be discussed.

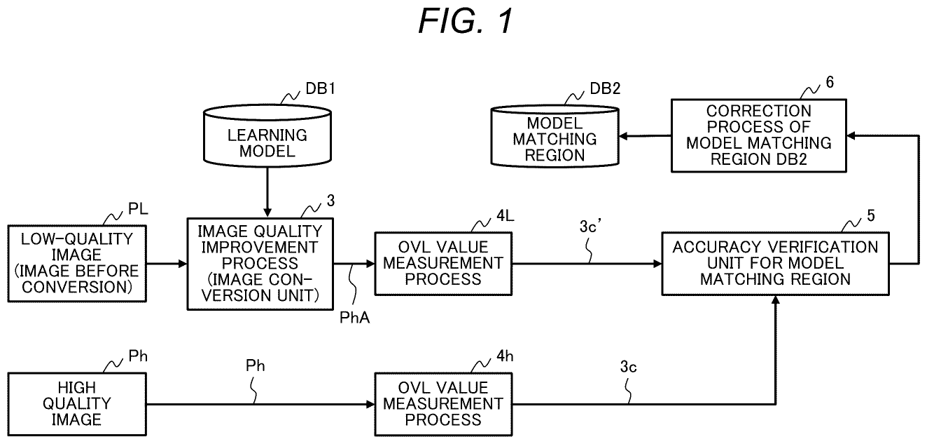

FIG. 1 shows a configuration example for particularly determining a model matching region in a matching region detection device for a learning model and a method thereof according to the first embodiment of the present invention.

In FIG. 1, PL is a low-quality image to be improved in image quality, Ph is a high-quality image that allows high-precision image measurement, and PhA is a high-quality image (hereinafter referred to as a quality-improved image) estimated from the low-quality image PL by AI processing. In addition, DB1 is a learning model, and 3 is an image quality improvement processing unit. Moreover, 5 is an accuracy verification unit for a model matching region, 6 is a correction processing unit for a model matching region, DB2 is a storage unit for a model matching region, 8 is an output result of measurement and determination results, and 4L and 4h are OVL value measurement processing unit.

In this configuration, the low-quality image PL is an electron microscope image captured with a small amount of electron beam irradiation. In the case of image measurement processing with a noisy image, the measurement may be disabled or the accuracy of measurement may decrease. Thus, the low-quality image PL is set. In contrast, the high-quality image Ph includes a reflection of an actual appearance of a portion to be observed and is to be referred to as a correct value. The high-quality image Ph is an image obtained by capturing multiple low-integration images PL of the same portion and obtaining the integration average of the images to remove noise.

In the learning model matching region detection device and the method thereof according to the present invention, with respect to the actual appearance, shape, and position of a portion to be observed as indicated by the high-quality image Ph, a quality-improved image is estimated by image improvement processing using AI on an image captured as the low-quality image PL, and a displacement of the appearance, shape, and position of the quality-improved image is detected.

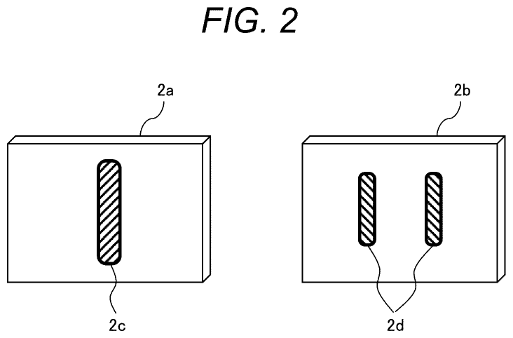

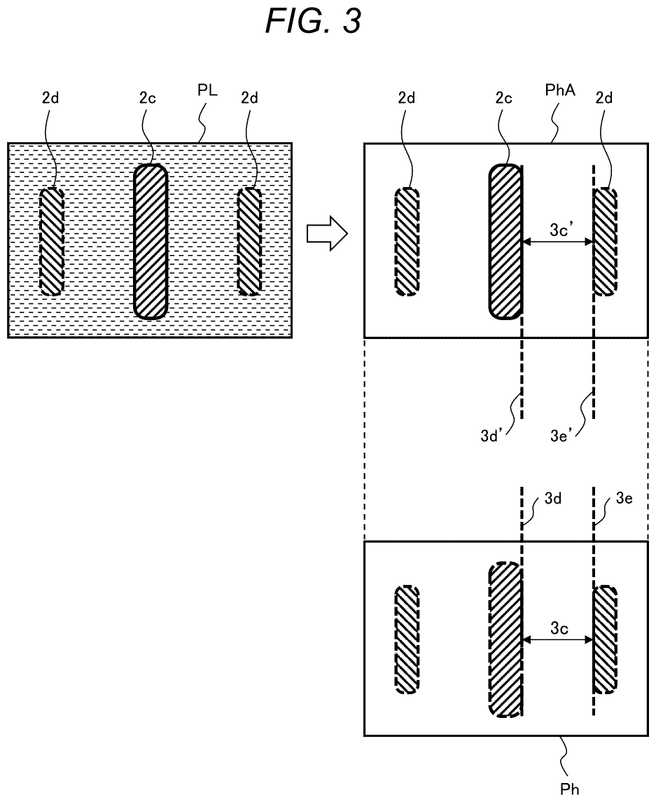

First, referring to FIGS. 2 and 3, an example of the low-quality image PL will be described below. In the following description, as an example of image measurement of a wafer chip, measurement (overlay measurement) of displacements (OVL values) of the upper and lower layers in a multilayer circuit structure will be shown as an example.

In FIG. 2, 2a indicates an example of an upper-layer circuit pattern, and 2c indicates an upper-layer circuit wiring. Furthermore, 2b indicate a lower-layer circuit pattern, and 2d indicates lower-layer circuit wirings. It is assumed that the circuit pattern 2a is formed on the circuit pattern 2b in a semiconductor manufacturing process.

FIG. 3 shows the relationship between the low-quality image and the quality-improved image and the high-quality image. FIG. 3 shows that the measured low-quality image PL on the left side is converted into the quality-improved image PhA on the upper right side by improving the image quality through machine learning. Moreover, FIG. 3 shows that the quality-improved image PhA is compared with the high-quality image Ph indicated in the lower part.

For the low-quality image PL, in addition to the upper-layer circuit pattern 2c, the lower-layer circuit patterns 2d hidden behind the upper layer can be imaged by changing the acceleration voltage of an electron beam or the position of an electron beam detector. The low-quality image PL on the upper left side of FIG. 3 schematically illustrates a large amount of particulate noise in a short imaging time.

The quality-improved image PhA on the upper right side of FIG. 3 is a quality-improved image of high quality that is obtained by converting the low-quality image PL using the image quality improvement processing unit 3. The image quality improvement processing unit 3 can be implemented using, for example, machine learning through a convolutional neural network (CNN) or the like. The CNN learns means for learning the low-quality image PL and the high-quality image Ph which is improved in image quality by the integration average, the low-quality image PL and the high-quality image Ph being captured at the same position, and for converting the low-quality image to the high-quality image. Hereinafter, the low-quality image and the high-quality image which are imaged at the same portion will be referred to as paired images. The learning model DB1 is a learning model for learning here. In addition, by using the learning model DB1, the low-quality image PL is converted into image quality corresponding to the high-quality image obtained by the integration average of the plurality of low-quality images.

The image quality improvement processing unit 3 removes noise from the low-quality image PL containing a large amount of particulate noise, so that the low-quality image PL is converted into the quality-improved image PhA of good image quality suitable for image measurement. In the converted quality-improved image PhA, the lower-layer circuit wirings 2d can be clearly recognized in addition to the upper-layer circuit wiring 2c, and edge positions 3d′ and 3e′ of the wirings and a distance 3c′ between the upper and lower wirings can also be clearly recognized.

In addition, for example, information about the high-quality image Ph obtained by the integration average of the low-quality images and measurement information about the converted quality-improved image PhA are compared with each other, so that a displacement between the images can be recognized. Differences between edge positions 3d and 3e of the wirings and a distance 3c in the high-quality image Ph and the edge positions 3d′ and 3e′ of the wirings and the distance 3c′ in the converted quality-improved image PhA can be recognized as displacements. In this case, the displacements are displacements caused by the learning model. In order to recognize the displacements, the OVL value measurement processing units 4L and 4h of FIG. 1 performs a measurement (overlay measurement) process on a displacement (OVL value) of the upper and lower layers of the multilayer circuit structure.

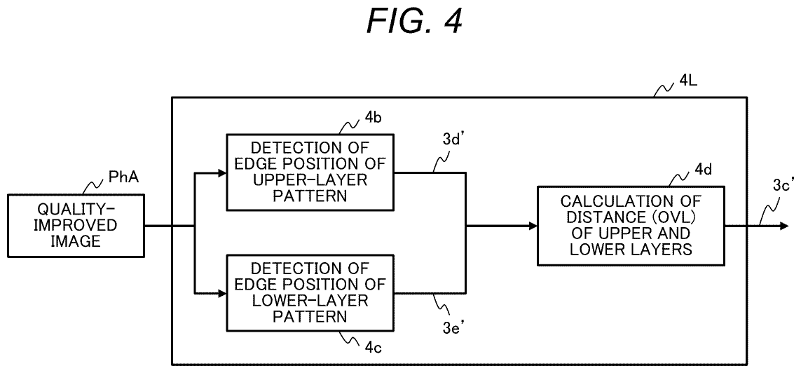

FIG. 4 shows a configuration example of the processing block 4L of OVL value measurement. The converted quality-improved image PhA is input to an edge position detection processing block 4b of the upper-layer pattern and an edge position detection block 4c of the lower-layer pattern, and the edge positions 3d′ and 3e′ are detected in the respective blocks. In the edge position detection processing block 4b of the upper-layer pattern, the edge position 3d′ of the upper-layer circuit pattern 2c in FIG. 3 is detected, whereas in the edge position detection block 4c of the lower-layer pattern, the edge position 3e′ of the lower-layer circuit pattern 2d is detected. In the distance calculation block 4d of the upper and lower layers, a distance 3c between the upper and lower layers is calculated from a difference between the detected positions of the edges of the upper and lower layers, and the distance is output as an OVL value.

Although the illustration is omitted, the same process is also performed in the processing block 4h of the OVL value measurement to measure the edge position 3d of the upper-layer pattern, the edge position 3e of the upper-layer pattern, and the distance 3c between the upper and lower layers.

In the accuracy verification unit 5 for the model matching region in FIG. 1, the accuracy verification process for the model matching region is performed using the distances 3c and 3c′ of the upper and lower layers from the processing blocks 4L and 4h of the OVL value measurement. In the following embodiments, an example of the model matching region defined by measurement accuracy information will be described. The model matching region can be defined by various methods using “image luminance information”, “noise amount information”, “edge feature amount”, and signal to noise ratio (SNR), a peak signal to noise ratio (PSNR), and structural similarity (SSIM) that are “image objective evaluation scales”, in addition to “measurement accuracy information”. In the present specification, these kinds of information are collectively referred to as measurement accuracy information. Furthermore, the measurement accuracy information can be used together with information about the reliability of the information. That is, it is preferable to manage that the process of accuracy is based on how much reliability.

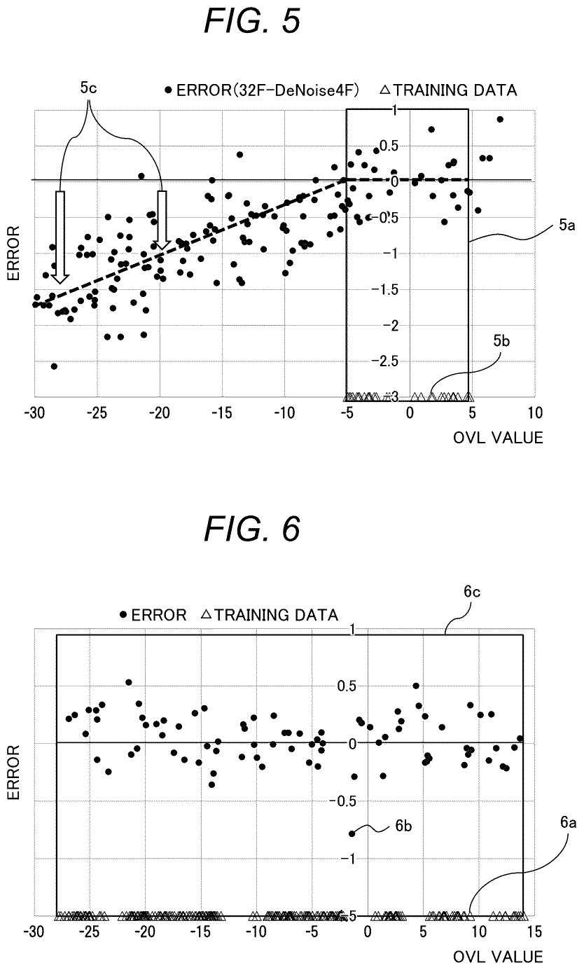

FIG. 5 shows an example of the relationship of errors in the learning region and other regions. In FIG. 5, the horizontal axis indicates an OVL value. A correction is made to set a certain reference value (e.g., a design value) to 0. The OVL of learning data is indicated by a triangular marker (5b). The measurement of an OVL value is indicated with reference to the high-quality image Ph.

Even when the design is made with OVL=0, the OVL value is not set to 0 but to variables due to variations between manufacturing devices. In this example, the OVL value is −5 to +5. The vertical axis indicates a difference (error) between an OVL value 3c determined from the high-quality image Ph and an OVL value 3c′ determined from the quality-improved image PhA.

A region (OVL value: −5 to +5) is a section of OVL values of learning data (hereinafter this section will be referred to as a learning region). In this region, errors are dispersed around the error of 0. As indicated by 5c, as the negative value of the OVL value increases, the center of the dispersion of errors increases to the negative side accordingly. This indicates that as the negative value of the OVL value increases, the OVL value determined from the quality-improved image PhA is smaller than the OVL value determined from the high-quality image Ph.

That is, it is assumed that this result is obtained because the learning model learns displacements of the upper and lower layers along with removal of particulate noise, the displacements being learned during learning, and the movement process of the upper and lower layers is performed such that the learned distances of the upper and lower layers during learning return to small distances when the low-quality image PL with a large negative OVL value is input.

Since such a phenomenon occurs, accuracy cannot be secured in a region of an OVL value having not been learned during learning. Thus, the initial state of the model matching region to be stored in the model matching region storage unit DB2 registers the range of OVL values, which are learned during the creation of the learning model, as a model matching region in association with the learning model. In the example of FIG. 5, the initial state of the model matching region is a region in which the OVL value ranges from −5 to +5.

However, depending on the learning model, accuracy may not be guaranteed in the range of OVL values learned during learning. FIG. 6 shows such an example.

FIG. 6 shows the state of occurrence of an error in the learning region. The OVL value of the learning data is indicated by a triangular marker 6a and is in a region (−28 to 14) indicated by 6c. In this section, errors are not uniformly dispersed and a large error occurs in a portion as indicated by 6b. Thus, the model matching region accuracy verification unit 5 performs a verification process of accuracy to find a region where a local error is likely to increase.

The model matching region accuracy verification unit 5 verifies accuracy as follows: First, the OVL value to be determined is denoted as x, a permissible value is set for a difference value between the OVL value 3c determined from the high-quality image Ph and the OVL value 3c′ determined from the quality-improved image PhA in a window within the window range of ±d with respect to x, and the permissible value is set as ±p (permissible error).

Assuming that the number of data points satisfying the permissible error in the window is expressed as N(kp(x)), the number of data points not satisfying the permissible error is expressed as N(kn(x)), and the ratio satisfying the permissible error is a permissible error achievement rate Ae(x), expression (1) is established.

$$\begin{matrix}[ Expression 1 ] & \\ Ae ( x ) = \frac{N ( kp ( x ) )}{N ( kp ) + N ( kn )} & ( 1 )\end{matrix}$$

In expression (1), the permissible error achievement rate Ae(x) represents the occurrence of an error in the window. Thus, a permissible error achievement rate Aeth is determined, and a model matching region is determined when Ae(x) exceeds Aeth. Hence, a model matching region determination function Mf(x) is determined as shown in expression (2).

$$\begin{matrix}[ Expression 2 ] & \\ Mf ( x ) = \{ \begin{matrix}inside model matching region ( Ae ( x ) \geq Aeth ) \\ outside model matching region ( Ae ( x ) \geq Aeth )\end{matrix} & ( 2 )\end{matrix}$$

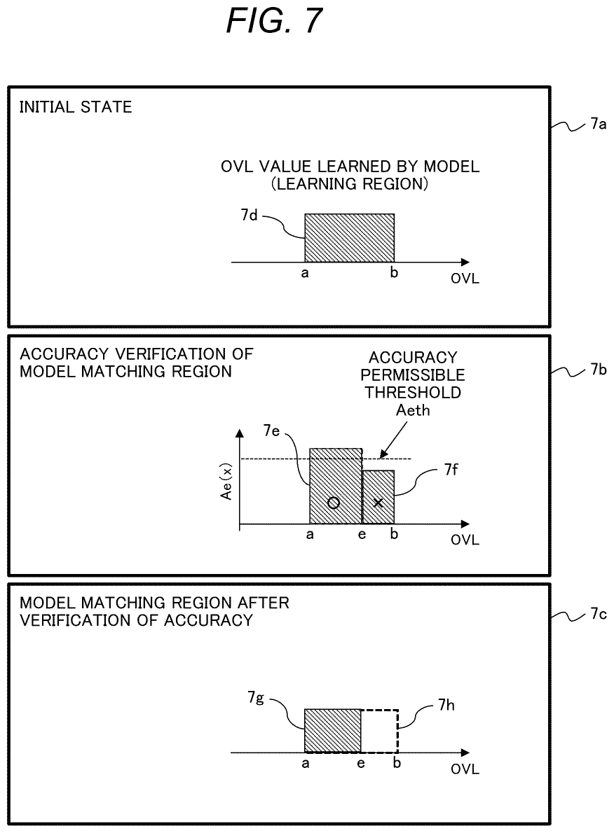

FIG. 7 shows a schematic diagram showing a state of transition of the model matching region, the transition being made by the accuracy verification unit 5 of the model matching region.

In FIG. 7, 7a indicates the initial state. In the initial state, the ranges of OVL value (learning regions) a and b of the learning image are set as the model matching region (7d) when the learning model is created.

In FIG. 7, 7b indicates the accuracy verification result of the model matching region in the initial state, the result being determined using the calculation method shown in expression (1). The permissible error achievement rate Ae(x) of regions a to e (7e) has a larger value than the permissible error achievement rate Aeth, and regions e to b (7f) have a smaller value than the permissible error achievement rate Aeth. Thus, according to expression (2), it is determined that the region 7e is the model matching region and the region 7f is outside the model matching region.

As a result, as indicated in 7c after accuracy verification, a region 7h determined to be located outside the model matching region is removed from the model matching region (7d) of the initial state, so that the regions a to e (7g) are set. As described above, according to the degeneration of the model region, the permissible error achievement rate Ae(x) at each value x in the model region may be registered or the function of expression (1) may be stored in the model matching region storage unit DB2. Thus, the reliability Ae(x) of the model can be displayed (presented) along with the inside/outside determination of the model matching region.

According to the result, through the correction process of the model matching region by the model matching region correction processing unit 6, the model matching region of the model matching region storage unit DB2 is corrected to the region 7g in association with the learning model used in the current image quality improvement process.

In this way, for the verification of the matching region of the learning model and the correction of the matching region of the learning model, the pair of the low-quality image PL and the high-quality image Ph is necessary. This process may be performed when the learning model DB1 is created, or the pair of the low-quality image PL and the high-quality image Ph may be collected during a test operation when the manufacturing line is under repair, and then the repair process of the model matching region storage unit DB2 may be performed.

The first embodiment described the case where the learning model matching region detection device and the method thereof are applied to the image quality improvement system and the length measuring system using the quality-improved image, but not limited to the image quality improvement system.

More generally, “including an accuracy conversion unit that converts low-accuracy information into accuracy improvement information with high accuracy by using a learning model; a model matching region storage unit that stores a region of learned information as a model matching region in the learning step of the learning model; a model matching region accuracy verification unit that verifies the accuracy of the accuracy improvement information with reference to the high-accuracy information; and a model matching region correction processing unit that corrects the model matching region in the model matching region storage unit by using the accuracy of the accuracy improvement information detected by the model matching region accuracy verification unit” makes it possible to apply to much wider range.

### Second Embodiment

The first embodiment described that accuracy in the model matching region is verified to correct the information of the model matching region storage unit DB2. In contrast, the second embodiment describes that a measured low-quality image is measured and determined by using a corrected model matching region.

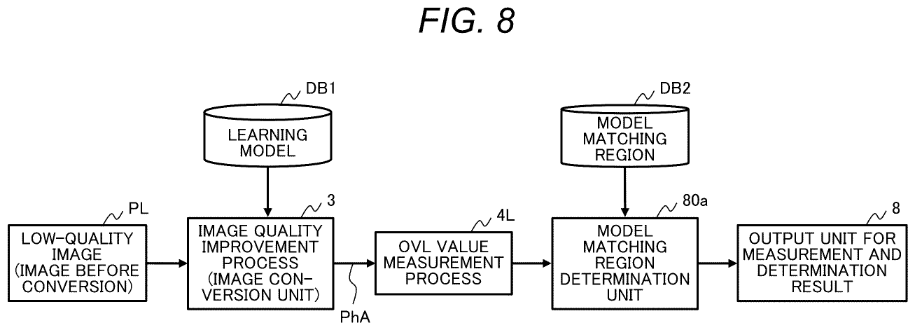

FIG. 8 shows a processing block when an actual operation is performed using information of a model matching region storage unit DB2 after accuracy in the model matching region is verified. During an actual operation, an image measurement process is performed only by using a low-quality image PL. An image quality improvement process is performed on the low-quality image PL by using a learning model DB1 in an image quality improvement processing unit 3, so that the low-quality image PL is converted into an quality-improved image PhA of high image quality. For the converted quality-improved image PhA, an OVL value is calculated using an OVL value measurement processing unit 4L.

A determination process is performed using the OVL value by a model matching region determination unit 80a. The determination is made using the information of the model matching region storage unit DB2. When the OVL value is a value outside the model matching region, warning information such as “the value is beyond the scope of the learning model and thus is unmeasurable” may be displayed using the output unit for measurement and determination result of 8, or “the OVL value is xx.x [nm]. The permissible error achievement rate is xx [%], proving that the reliability of accuracy is low.” (xx is a measured value or a numeric value of reliability and the like) may be displayed using 8.

According to the present embodiment, measurement data satisfying the accuracy of measurement can be acquired in the learning region of the selected learning model.

### Third Embodiment

The embodiments 1 and 2 described the examples about the verification of accuracy in the learning region, and there are cases of poor accuracy in the learning region, and measures against poor accuracy are described. A third embodiment will describe the verification of accuracy outside a learning region and a method for correcting a model matching region. The correction means an extension or change of the model matching region.

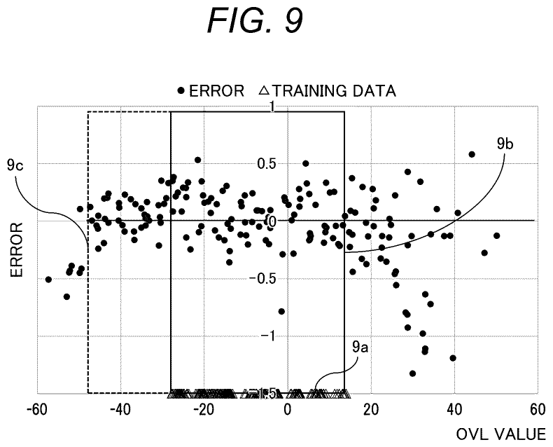

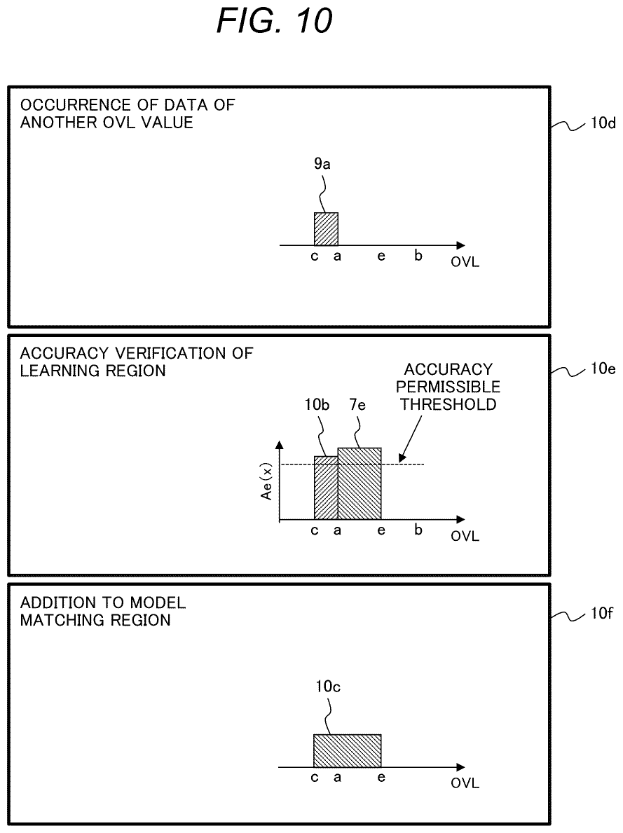

FIG. 9 shows a state of dispersion of errors outside the learning region using a learning model. Here, 9a is an OVL value of learning data, and 9b is the learning region indicating the range of OVL values of the learning data. A region on the right side of 9b is outside the learning region and thus contains large errors. However, a region 9c in the range of the left side of 9b does not contain large errors. FIG. 9 shows a result different from that of FIG. 5. That is, depending on the used learning model, there is a case where an error does not increase outside the learning region. Thus, if the accuracy is verified outside the learning region to confirm the accuracy, a model matching range associated with the used learning model can be extended.

The extension of the model matching range outside the learning region can be processed with the same processing configuration as the processing block shown in FIG. 1 according to the first embodiment. Although the accuracy is verified using the low-quality image PL and the high-quality image Ph in the learning region in the first embodiment, it is necessary to acquire a pair of images outside the learning region in the present embodiment. For example, such data may be collected during a test operation when the manufacturing process is changed. In an accuracy verification unit 5 of a model matching region, image data is necessary according to a window width determined in advance as shown in expression (1), requiring a plurality of pieces of image data for satisfying the window width. Hereinafter, the image data is referred to as an image group.

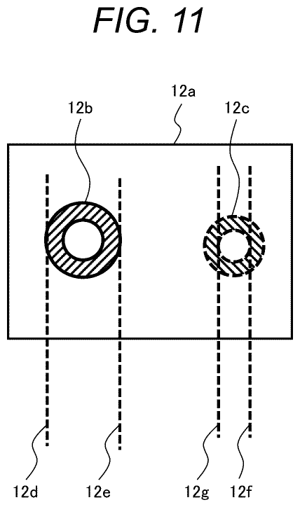

FIG. 10 shows a schematic diagram showing a transition of the model matching region outside the learning region. FIG. 10 shows a scenario in which accuracy is verified outside the learning region after the accuracy of the model matching region is verified inside the learning region described in FIG. 7.

In FIG. 10, 10d shows an example in which another image group of OVL values appears outside the learning region. FIG. 7 shows an example in which a and b indicate a learning region and another image group of OVL values is photographed on the left side. These image groups undergo an accuracy verification process in the accuracy verification unit of the model matching region in 5, and a permissible error achievement rate Ae(x) is determined.

The determined result is shown in 10e. The permissible error achievement rate of a newly generated section 9a is 10b, which exceeds an accuracy permissible threshold. This indicates that the section is located in the model matching region. Here, 10f shows a state in which the result is added to the model matching region described in FIG. 7. Shown in FIG. 7. 10f shows that the model matching section with the permissible error achievement rate Ae(x) (7e) of data in the learning region is combined, and the added model matching sections are c to e (10c). These results are registered in the model matching region storage unit of DB2 while being associated with the used learning model.

An actual operation is processed in the processing block shown in FIG. 8 as in the second embodiment, and the measurement result and the accuracy determination result are output.

According to the present embodiment, measurement data satisfying the accuracy of measurement can be acquired also outside the learning region of the selected learning model.

The combined adoption of the present embodiment and the first embodiment can acquire length measuring data that satisfies the accuracy of measurement in the model matching section in which the accuracy of measurement has been verified.

Furthermore, as another method of the present method, another learning model is created in a wide range of OVL values to extend the model matching region. In this case, in order to reconstruct (relearn) the learning model, a confirmation work is generated with a long calculation time and accuracy, and a confirmation work in association with switching of the learning model is generated. In the present method, the learning model is not changed. The method maximizes the use of the model matching range of an existing learning model. Expressions (1) and (2) used in the present method are simple calculations, and the necessary calculation amount is considerably smaller than that during the reconstruction of the learning model, thereby being capable of completing a changing operation of the matching range in a short time.

FIG. 3 shows an example of application to the measurement (OVL measurement) of a displacement of the upper and lower layers. As an example of the side effect of image quality improvement with AI, an unnecessary line width correction may be made to bring the line width of a circuit pattern close to the line width of a learned image, or when a circular pattern shape in FIG. 11 is learned, an unnecessary correction may be made close to the size of the learned circular shape. Also in this case, the method used in the present invention is applicable. The model application region is preferably defined by a line width or the sizes of the inside diameter and the outside diameter of a circular shape. The reliability of a measured value obtained from a quality-improved image can be guaranteed by the line width or the outside diameter and the inside diameter of the model matching region. Otherwise as described in the first to third embodiments of the present invention, warning information such as “accuracy cannot be guaranteed” may be presented or the degeneration or extended correction may be performed in the model matching region.

The present invention can provide a matching region detection device for a machine learning model and a method thereof that are suitable for verification and correction of a matching region of a learning model in machine learning.

Specifically, according to embodiments of the present invention, a reduction in the accuracy of measurement in image measurement can be recognized by a notification about a mismatched learning model. This can prevent a reduction in the accuracy of measurement when using an improperly converted image.

Furthermore, according to the embodiments of the present invention, even in a measurement region where a learning model used in advance is not registered as a model matching region, the model matching region of the learning model can be added or deleted by verifying the accuracy of measurement during an operation.

### Fourth Embodiment

The foregoing embodiments described the learning model matching region detection device and the method thereof. In contrast, a fourth embodiment will describe a learning model operation method using the device and method.

As is understood from the first to third embodiments, the learning model operation method is an operation described in two steps: the learning step of a learning model and the operating step of the learning model. In short, a relearning method is ordinarily adopted when the appropriateness of the learning model initially generated in learning decreases in the subsequent operation. In this case, instead of relearning with a heavy load, the matching region of an initial learning model is changed according to detection accuracy in a normal operation.

Thus, the learning model operation method of the fourth embodiment “includes the learning step of obtaining a learning model for estimating a quality-improved image from a low-quality image using AI and storing the region of learned information as a model matching region; and an operation step of determining whether an accuracy improving state is information about the model matching region of the learning model on the basis of the information of the model matching region when the quality-improved image is estimated from the low-quality image by using the learning model and an image is measured using the quality-improved image, verifying the accuracy improving state with reference to the high-accuracy information, and correcting the model matching region by using the accuracy of the accuracy improving state”.

### Fifth Embodiment

The foregoing embodiments described that for the measured low-quality image, the quality-improved image of high image quality is obtained by using the learning model. However, the application example of the present invention is not limited to image quality.

The present invention is applicable if low-accuracy information is increased in accuracy by using a learning model. This is because the present invention provides measures against an unnecessary displacement occurring as a side effect due to the learning model when the accuracy is improved using the learning model. Such a problem always occurs when the accuracy is improved using the learning model.

Thus, the present invention is applicable also when low-accuracy information replacing the low-quality image includes a measured voice or a pressure, a temperature, or vibrations in various plants. In this case, the present invention is configured as “a learning model matching region detection device including: an improvement processing unit that converts low-accuracy information into improvement information with high accuracy by using a learning model; a model matching region storage unit that stores a region of learned information as a model matching region in the learning step of the learning model; a model matching region accuracy verification unit that verifies the accuracy of a measured value determined from the improvement information with reference to the measured value of high-accuracy information; and a model matching region correction processing unit that corrects the model matching region in the model matching region storage unit by using the accuracy of the accuracy improvement information detected by the model matching region accuracy verification unit”.

### Sixth Embodiment

In a sixth embodiment, matters described in the first to fourth embodiments will be summarized.

In the matching region detection device for the learning model according to the present invention in FIG. 1, three kinds of images are handled. The method of determining the images and the characteristics of the images will be summarized as follows.

First, a low-quality image PL is a SEM image obtained by a small amount of electron beam irradiation on a portion to be observed, and the image contains particulate noise. Therefore, when image measurement is conducted using this image, a measurement error may occur.

In contrast, a high-quality image Ph includes a reflection of an original and correct appearance of a portion to be observed, and is to be referred to as a correct value. The high-quality image Ph is an image obtained by capturing multiple low-quality images PL and obtaining the integration average of the images. Particulate noise contained in the low-quality image PL are randomly generated noise and thus can be removed by the integration average process. However, the amount of electron beam irradiation increases and causes damage to a wafer and thus the high-quality image Ph obtained by multiple times of irradiation cannot be obtained frequently. Thus, only when the learning model is created, the high-quality image Ph is obtained while accepting damage.

The quality-improved image PhA is a high-quality image estimated from the low-quality image PL by AI processing using the learning model. In order to distinguish the name from the high-quality image Ph determined from the integration average of the above-mentioned low-quality images PL, the image is referred to as the quality-improved image PhA. The quality-improved image PhA is obtained by estimating, on the basis of the learning model, a noise-free image by AI from the single low-quality image. In this case, if an improper learning model is used, such a side effect may occur that a displacement of the upper and lower layers is arbitrarily corrected. In contrast, the high-quality image determined from the integration average of the low-quality image does not cause such a side effect.

In the learning model matching region detection device and the method thereof according to the present invention, with respect to the original and correct appearance, shape, and position of a portion to be observed as indicated by the high-quality image Ph, a displacement of the actual appearance, shape, and position of a portion to be observed is detected as indicated by the low-quality image PL indicating an observation portion of an actually manufactured product.

However, since the low-quality image PL cannot increase in detection accuracy, the low-quality image PL is converted into the quality-improved image PhA of high quality by machine learning, and then is compared with the high-quality image Ph.

The comparison is made in consideration of the characteristics and features of the three kinds of images and relates to a measured value (OVL values 4L and 4h) determined by image measurement.

As a measured value determined by image measurement, first, in the case of the low-quality image PL, the edge portion of the circuit pattern is unclear due to noise and thus cannot be measured. In the case of a measured value determined by the high-quality image Ph, “the design value of a displacement of the upper and lower layers” includes “an error of a manufacturing process factor”. In contrast, in the case of a measured value determined by the quality-improved image PhA, “the design value of a displacement of the upper and lower layers” includes “an error of a manufacturing process factor” and “an unnecessary displacement (side effect) caused by improving image quality with AI”.

In view of such characteristics and features, a matter to be implemented by the present invention is to recognize a region (model matching region) where “an unnecessary displacement (side effect) caused by improving image quality with AI” is small. If “an unnecessary displacement (side effect) caused by improving image quality with AI” is small, the size of “an error of a manufacturing process factor” can be measured with accuracy.

With reference to “the design value of a displacement of the upper and lower layers in the high-quality image Ph based on design information of a portion to be observed”, “a measured value determined from the quality-improved image”—“the design value of a displacement of the upper and lower layers in the high-quality image Ph based on design information of a portion to be observed” is “an error of a manufacturing process factor”+“an unnecessary displacement (side effect) caused by improving image quality with AI”. That is, an error is determined as a combination of “an error of a manufacturing process factor” and “an unnecessary displacement (side effect) caused by improving image quality with AI”, so that “an unnecessary displacement caused by improving image quality with AI” cannot be recognized.

At this time, in order to determine “an unnecessary displacement caused by improving image quality with AI”, “a measured value determined from a quality-improved image”−“a measured value determined from a quality-improved image” is “an unnecessary displacement (side effect) caused by improving image quality with AI”, so that “an unnecessary displacement caused by improving image quality with AI” can be recognized.

In view of the foregoing features shown in the images, the present invention is configured to achieve high accuracy by using the relationship.

### REFERENCE SIGNS LIST

PL: low-quality image
Ph: high-quality image
DB1: learning model
3: image quality improvement processing unit
4 (4L, 4h): OVL value measurement processing unit
5: accuracy verification unit for model matching region
6: correction processing unit for model matching region
DB2: storage unit for model matching region

1. A learning model matching region detection device comprising: an image quality improvement processing unit that converts a low-quality image into a quality-improved image as a high-quality image by using a learning model; a model matching region storage unit that stores a region of learned information as a model matching region in a learning step of the learning model; a model matching region accuracy verification unit that verifies accuracy of a measured value determined from the quality-improved image with reference to a measured value of the high-quality image; and a model matching region correction processing unit that corrects the model matching region in the model matching region storage unit by using the accuracy of accuracy improvement information detected by the model matching region accuracy verification unit.

2. The learning model matching region detection device according to claim 1, further comprising
a model region determination unit that determines whether the accuracy improvement information is information about the model matching region of the learning model on a basis of information about the model matching region of the model matching region storage unit.

3. The learning model matching region detection device according to claim 1, wherein
information about the low-quality image is information about a low-quality image of a target product, and information about the high-quality image is information about a high-quality image of the target product.

4. The learning model matching region detection device according to claim 1, wherein
a correction of the model matching region of the model matching region storage unit in the model matching region correction processing unit is to change a part of the model matching region or to extend the model matching region.

5. The learning model matching region detection device according to claim 4, wherein
the model matching region of the model matching region storage unit in the model matching region correction processing unit is corrected by adding measurement accuracy information and reliability information about the model matching region.

6. The learning model matching region detection device according to claim 5, wherein
the measurement accuracy information is one of an image measurement value, image luminance information, noise amount information, an edge feature amount, and an image objective evaluation scale.

7. The learning model matching region detection device according to claim 5, wherein
the model region determination unit determines whether the accuracy improvement information is executed in a model region from a measurement result of the accuracy improvement information, and when the accuracy improvement information is not executed, a warning is output, and a measured value is output with the measurement accuracy information or the reliability information.

8. The learning model matching region detection device according to claim 3, wherein
the target product is a semiconductor having a multilayer structure, and information about the low-quality image is a distance between an upper layer and a lower layer of a semiconductor pattern.

9. The learning model matching region detection device according to claim 7, wherein
a line width in the semiconductor having the multilayer structure is detected.

10. A method for detecting a learning model matching region, the method comprising: converting a low-quality image into a quality-improved image as a high-quality image by using a learning model; storing a region of learned information as a model matching region in a learning step of the learning model; verifying accuracy of a measured value determined from the quality-improved image with reference to a true measured value; and correcting the model matching region by using the accuracy of accuracy improvement information.

11. The learning model matching region detection method according to claim 10, further comprising
determining whether the accuracy improvement information is information about the model matching region of the learning model on a basis of information about the model matching region.

12. A learning model operation method comprising: a learning step of obtaining a learning model for estimating a quality-improved image from a low-quality image using AI and storing a region of learned information as a model matching region; and an operation step of determining whether an accuracy improving state when, by using the learning model, the quality-improved image is estimated from the low-quality image and an image is measured using the quality-improved image is information about the model matching region of the learning model on the basis of the information about the model matching region, verifying the accuracy improving state with reference to the high-accuracy information, and correcting the model matching region by using accuracy of the accuracy improving state.

13. A learning model matching region detection device comprising: an improvement processing unit that converts low-accuracy information into improvement information with high accuracy by using a learning model; a model matching region storage unit that stores a region of learned information as a model matching region in a learning step of the learning model; a model matching region accuracy verification unit that verifies accuracy of a measured value determined from the improvement information, with reference to a measured value of high-accuracy information; and a model matching region correction processing unit that corrects the model matching region in the model matching region storage unit by using the accuracy of accuracy improvement information detected by the model matching region accuracy verification unit.

14. The learning model matching region detection device according to claim 2 wherein
information about the low-quality image is information about a low-quality image of a target product, and information about the high-quality image is information about a high-quality image of the target product.

15. The learning model matching region detection device according to claim 14, wherein
the target product is a semiconductor having a multilayer structure, and information about the low-quality image is a distance between an upper layer and a lower layer of a semiconductor pattern.
